(19) United States
(12) Patent Application Publication
(10) Pub. No.: US 2026/0141160 A1
(43) Pub. Date: May 21, 2026

(54) METHOD FOR GENERATIVE HETEROGENEOUS LOGIC OPTIMIZATION BASED ON CRITICAL PATH PARTITIONING

(71) Applicant: HANGZHOU DIANZI UNIVERSITY, Hangzhou (CN)

(72) Inventors: Yue WU, Hangzhou (CN); Yilong ZHOU, Hangzhou (CN); Lingfeng ZHOU, Hangzhou (CN); Jiayi DING, Hangzhou (CN); Xiaoyan YANG, Hangzhou (CN)

(21) Appl. No.: 19/387,175

(22) Filed: Nov. 12, 2025

(30) Foreign Application Priority Data
Nov. 15, 2024 (CN) 2024116321805

(51) Int. Cl. G06F 30/398; G06F 30/392

(52) U.S. Cl. CPC G06F 30/398; G06F 30/392

(57) ABSTRACT

The application provides a method for generative heterogeneous logic optimization based on critical path partitioning. The method includes: converting a digital logic circuit into an And-Inverter Graph (AIG) format; partitioning the AIG using reinforcement learning based on critical path information of the circuit to obtain critical-path-aware partitions so as to reduce influence of critical path changes brought by the partitioning on timing performance; respectively and automatically exploring an optimized structure and synthesis flow suitable for each partition using the reinforcement learning method; selecting optimization operators for various structures using a reinforcement learning agent guided by area-delay metrics and optimizing each partition; and merging the optimized partitions in the AIG format. In the application, the digital logic circuit is partitioned based on critical paths, and reinforcement learning is used to explore and optimize structures and strategies based on area and delay.

### CROSS-REFERENCE TO RELATED APPLICATIONS

This application claims the benefit and priority to Chinese Patent Application No. 2024116321805, filed on Nov. 15, 2024. The DAS code for the priority application is 0B81.

### TECHNICAL FIELD

The application belongs to the field of electronic design automation technology, and more particularly, to a method for generative heterogeneous logic optimization based on critical path partitioning.

### BACKGROUND

With the increasing complexity of chip architectures, if high-efficiency optimization may be performed in the logic optimization stage in the chip design flow in a targeted manner, a chip with reduced area and enhanced performance may be obtained. The partitioning and logic synthesis structure selection of each structure area of the chip have the greatest influence on the delay and the power consumption of the chip after logic optimization. The reasonable circuit partitioning method may greatly reduce the influence on the timing performance of the chip, and a targeted logic optimization flow may directly improve the final area, delay and the power consumption of the chip.

Current logic optimization methods have limitations, as they typically employ a single structure or a fixed heterogeneous optimization flow. These methods fail to address the heterogeneous nature of chips and do not fully explore the optimization space. Traditional circuit partitioning algorithm adopts on traditional graph partitioning algorithm, which only includes circuit topology information and lacks other essential circuit-specific details. The traditional logic optimization algorithm adopts a fixed optimization flow and cannot adapt to different circuit structures. Given the massive scale and complex architecture of modern chips, traditional logic optimization methods are inadequate for effective processing. Therefore, there is an urgent need for a graph partitioning algorithm that considers circuit information to partition circuits and generate different optimization flows based on different partitioning structures for circuit logic optimization.

### SUMMARY

The application aims to solve the problems that the traditional partitioning method lacks circuit information and logic optimization cannot fully explore an optimization space, and provides a method for generative heterogeneous logic optimization based on critical path partitioning. In the method, a digital logic circuit is converted into an AIG graph format, and the AIG is partitioned by using reinforcement learning based on critical path information of the circuit, and a critical-path-aware partitioning is obtained, so as to reduce the influence of critical path change caused by the partitioning on timing performance. The partitioned circuits are automatically explored by using reinforcement learning methods for optimization structures and synthesis flows suitable for each partition. The reinforcement learning agent, guided by area and delay objectives, selects the most suitable optimization operators to optimize each partition. Finally, the optimized partitions are merged in an AIG form. By partitioning digital logic circuits based on critical paths and using reinforcement learning to explore optimization structures and strategies based on area and delay, the present application reduces the influence of partitioning on timing performance, jumps out of a local optimal solution, obtains a global better solution, and automatically explores without manual intervention, thereby reducing the labor cost in chip design.

In order to solve the above problems, the application provides a method for generative heterogeneous logic optimization based on critical path partitioning, and the method includes:
step S1: constructing a reinforcement learning partitioning agent model for a critical path of a digital logic circuit;
step S2: partitioning the digital logic circuit using the reinforcement learning partitioning agent model for the critical path of the digital logic circuit to obtain a plurality of partitioned circuits;
step S3: automatically exploring optimization space on the plurality of partitioned circuits by a reinforcement learning optimization model to obtain a plurality of optimized partitioned circuits; and
step S4: merging the optimized partitioned circuits to obtain a final optimization result.

In one embodiment, the step S1 specifically includes:
S101: constructing a digital logic circuit conversion graph:
acquiring different digital logic circuits to construct a dataset;
converting the digital logic circuits in the dataset into an AIG (And-Inverter Graph) format, to obtain the digital logic circuit conversion graph;
simplifying logic functions into AND and NOT operations based on logic function descriptions in an original digital logic circuit, wherein in the digital logic circuit conversion graph, each mode represents an AND function, each edge represents a connection relationship between nodes, and each edge in a inverted state represents a NOT function;
S102: marking a circuit critical path:
marking the circuit critical path onto the digital logic circuit conversion graph obtained in the step S101, wherein the circuit critical path is a path with longest delay in the digital logic circuit, that is, a path with most levels in the digital logic circuit conversion graph;
finding out corresponding nodes and edges between the nodes on the digital logic circuit conversion graph obtained in the step S101 for all critical path nodes, marking them as the critical path, and obtaining a to-be-partitioned circuit representation graph with critical path information;
the marking the circuit critical path comprises: performing a depth-first search on all POs (Primary Outputs) in the digital logic circuit; traversing a child node of each node in all paths from the POs; for each child node, determining that the child node belongs to the circuit critical path if it is not a PI (Primary Input) and its level number is one less than that of its parent node; otherwise, determining that the child node does not belong to the circuit critical path; and repeating the traversing and determining steps until all nodes belonging to the circuit critical path are identified.
S103: training the partitioning model:
performing partitioning operations on the to-be-partitioned circuit representation graph with critical path information using a reinforcement learning A2C model, and calculating a single-step partitioning reward function rₜ to update model parameters;
the single-step loss function during the training the reinforcement learning A2C model is:

$$L ( θ ) = - {\sum }_{t = 0}^{T - 1} log {π}_{θ} ( {a}_{t} \vert {s}_{t} ) ( {R}_{t} - {v}_{θ} ( {s}_{t} ) ) + α {\sum }_{t = 0}^{T - 1} {( {R}_{t} - {v}_{θ} ( {s}_{t} ) )}^{2} \qquad ( 1 )$$

$${R}_{t} = {\sum }_{k = 0}^{T - t - 1} {γ}^{k} {r}_{t + 1 + k} \qquad ( 2 )$$

where θ represents a model parameter, sₜ represents a graph state at time t, aₜ represents an action selected at time t, π_{θ}(aₜ|sₜ) represents probability distribution of aₜ at sₜ>v_{θ}(sₜ) represents an estimated value of sₜ, α represents a loss coefficient, Rₜ represents a cumulative reward function, γ represents a discount factor, rₜ₊₁₊ₖ represents a single-step reward function at time t+1+k;
the single-step reward function rₜ at time t after introducing the circuit critical path, is:

$${r}_{t} = [ n c ( {s}_{t} ) - n c ( {s}_{t + 1} ) ] {δ}^{m} \qquad ( 3 )$$

$$nc ( G ) = c u t ( G ) ( \frac{1}{vol ( {V}_{1} )} + \frac{1}{vol ( {V}_{2} )} + … + \frac{1}{vol ( {V}_{n} )} ) \qquad ( 4 )$$

$$vol ( {V}_{Q} ) = {\sum }_{v ∈ {V}_{Q}} deg ( v ) \qquad ( 5 )$$

where sₜ₊₁ is a graph state after performing a single-step partitioning operation; δ is a critical path factor; m is a number of times the critical path is cut for current partitioning; nc is a partitioning normalization function; G is a partitioned graph state; Vn represents partition n; vol is a partitioning volume function; cut function counts a number of edges cut by partitioning; Q is a partition index; Q∈[1, n], deg(v) is a degree function of nodes.
S104: repeating steps S101 to S103 for all digital logic circuits in the dataset until the reinforcement learning A2C model converges, thereby obtaining the reinforcement learning partitioning agent model for the critical path of the digital logic circuits.

In one embodiment, the step 2 includes:
S201: performing graph partitioning on the digital logic circuit:
converting the digital logic circuit to be partitioned into an AIG format, and inputting it into a trained reinforcement learning graph partitioning agent model for partitioning, to obtain graph partitioning information about the critical path;
s202: performing circuit partitioning on the digital logic circuit:
converting the graph partitioning information into node partitioning information; performing circuit partitioning on the original digital logic circuit based on the node partitioning information; and
traversing each node of the original digital logic circuit for each circuit partition, and constructing a partitioned circuit based on partitioning information of each node, which includes:
traversing each node in each circuit partition, if the current node is a PI or PO of the original digital logic circuit, adding it as a PI or PO in the partitioned circuit; if the current node is neither a PI nor a PO, and a fan-in node of the current node belongs to a same partition as the current node, adding the current node to the partitioned circuit; if the current node is neither a PI nor a PO, and a fan-in node of the current node does not belong to the same partition as the current node, adding the fan-in node as a PI in the partitioned circuit; if the current node is neither a PI nor a PO, and a fan-out node of the current node does not belong to the same partition as the current node, adding a fan-out node of the current node as a PO in the partitioned circuit; if the current node is neither a PI nor a PO, and a fan-out node of the current node belongs to the same partition as the current node, adding the current node to the partitioned circuit.

In one embodiment, the step 3 includes:
S301: initializing:
initializing each partitioned circuit to determine an optimization environment and set an exploration iteration length;
S302: selecting an optimization operator:
extracting features of the partitioned circuit, and feeding a result obtained after standardizing the features of the partitioned circuit and history data of a plurality of optimization operators into the reinforcement learning optimization model, to select a most suitable optimization operator for the current partitioned circuit;
the features of the partitioned circuit comprise a number of nodes in the digital logic circuit conversion graph, a number of edges, a number of levels of the circuit corresponding to the AIG, a number of latches, a proportion of AND gates and NOT gates; a maximum number of fan-ins and a maximum number of fan-outs of the digital logic circuit after process mapping, and an average number of fan-ins and an average number of fan-outs of logic nodes;
S303: optimizing the partitioned circuit:
optimizing the partitioned circuit based on the selected optimizing operator, and calculating a single-step optimization reward function to update the reinforcement learning optimizing model;
the single-step optimized reward function is:

$$r ( k ) = v ( {s}_{k} ) - v ( {s}_{k + 1} ) \qquad ( 6 )$$

$$v ( {s}_{k} ) = c * {V}_{delay} + ( 1 - c ) * {V}_{area} \qquad ( 7 )$$

where V_{delay} and Vₐᵣₑₐ are a delay and the area, respectively, of the partitioned circuit after the process mapping, c is a weight coefficient, sₖ represents a state of the circuit at time k, k represents an iteration count.
S304: repeating steps S302 and S303 until a maximum iteration count is reached, and obtaining a plurality of optimized partitioned circuits.

In one embodiment, the step S4 includes:
based on partitioning information of each original node, traversing a PO of each optimized partitioned circuit, determining whether the PO is a PO of the original digital logic circuit, if so, adding the PO as a PO in the merged circuit, and if not, indicating that the PO is an internal node in the original digital logic circuit, and adding the internal node to the merged circuit;
traversing internal nodes of each optimized partitioned circuit, and adding corresponding internal nodes in the merged circuit correspondingly;
traversing a PI of each optimized partitioned circuit, determining whether the PI is a PI of the original digital logic circuit, if so, adding the PI as a PI in the merged circuit, and if not, indicating that the PI is an internal node in the original digital logic circuit, and adding the internal node to the merged circuit.

The beneficial effects of the application are as follows.

The method for the generative heterogeneous logic optimization based on the critical path partitioning provided by the application provides the following advantages. On one hand, an original circuit is partitioned by using a reinforcement learning model for the critical path partitioning of a digital logic circuit obtained through training of the digital logic circuit, so as to adapt to heterogeneous characteristics of modern chip design. On the other hand, the optimization space is automatically explored by using the reinforcement learning optimization model, and deeper optimization space is explored by taking the area and the delay as guiding, and does not depend on the optimization experience of research personnel, so that a better digital logic circuit is obtained at lower cost, compared to traditional fixed-flow logic optimization methods.

### DESCRIPTION OF THE DRAWINGS

FIG. 1 is a flowchart of a method for generative heterogeneous logic optimization based on critical path partitioning.

FIG. 2 is a flowchart of sub-steps of S1 in the method for generative heterogeneous logic optimization based on critical path partitioning provided by the present application.

FIG. 3 is a flowchart of sub-steps of S2 in the method for generative heterogeneous logic optimization based on critical path partitioning provided by the present application.

FIG. 4 is a flowchart of sub-steps of S3 in the method for generative heterogeneous logic optimization based on critical path partitioning provided by the present application.

FIG. 5 is a schematic diagram of circuit and AIG structure conversion in the method for the generative heterogeneous logic optimization based on critical path partitioning provided by the present invention.

FIG. 6A is a schematic diagram of circuit partitioning in the method for generative heterogeneous logic optimization based on critical path partitioning provided by the present application.

FIG. 6B is a schematic diagram of another circuit partitioning in the method for generative heterogeneous logic optimization based on critical path partitioning provided by the present application.

### DETAILED DESCRIPTION OF PREFERRED EMBODIMENTS

The principles and features of the method for generative heterogeneous logic optimization based on critical path partitioning provided by the present application are described in further detail below with reference to the drawings. The examples are provided for illustration only and not for limiting the scope of the application. It should be noted that the drawings are shown in a very simplified form and in a non-precise scale, merely for the purpose of facilitating clear and concise illustration of the embodiments of the present application. Furthermore, the structures shown in the drawings are often part of actual structures. In particular, as each drawing aims to highlight different aspects, different scales may be employed.

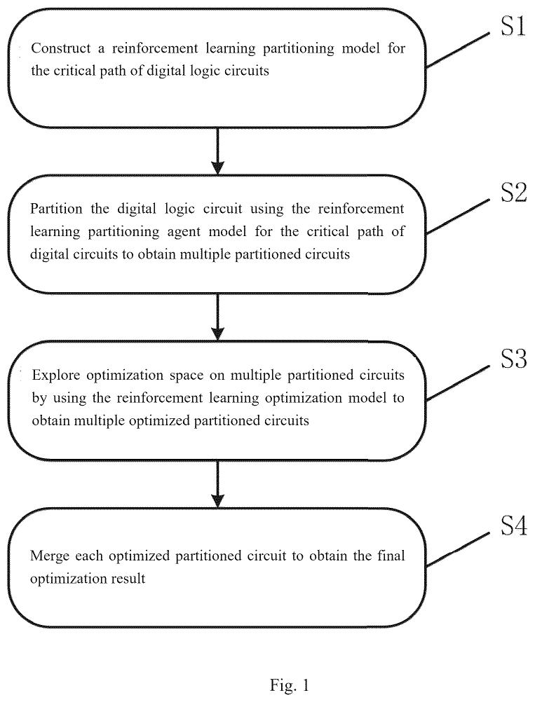

The application provides a method for generative heterogeneous logic optimization based on critical path partitioning, which is shown in a flowchart of FIG. 1 and includes S1, S2, S3 and S4. Embodiments of the present application are described in detail below.

The present application employs a reinforcement learning method to partition the circuit representation graph to be partitioned based on a reinforcement learning A2C model, and explores optimization space on the partitioned circuit. The A2C model is a deformation of an A3C model proposed by Google DeepMind team on an ICML conference in 2016, and belongs to the prior art. The model consists of a critic network and an actor network. The model may better complete the digital logic circuit partitioning and the optimization space exploration task through the design adjustment of a reward function and a loss function by updating strategy gradient through an advantage function.

The method for the generative heterogeneous logic optimization based on the critical path partitioning specifically includes S1-S4.

In S1, a reinforcement learning partitioning agent model for a critical path of a digital logic circuit is constructed.

In constructing a reinforcement learning partitioning model for the digital logic circuit, a training dataset is a Verilog file describing the digital logic circuit. The Verilog file is converted into a graph format, and is learned by the reinforcement learning agent for the critical path partitioning, to measure partitioning quality, and update model parameters based on partitioning results.

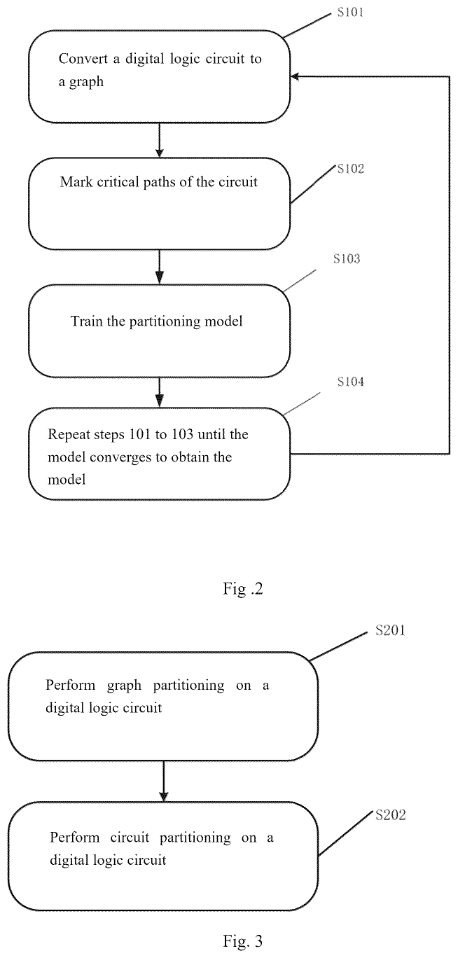

The S1 includes S101-S104, the flowchart of which is shown in FIG. 2.

In S101, a digital logic circuit conversion graph is constructed.

Different digital logic circuits are acquired to construct a dataset.

The digital logic circuits in the dataset into an AIG (And-Inverter Graph) format are converted to obtain the digital logic circuit conversion graph, that is AIG. Logic functions are simplified into AND and NOT operations based on logic function descriptions in an original digital logic circuit, which are represented by nodes and edges in AIG, that is, each node represents an AND function, each edge represents a connection relationship between nodes, and each edge in an inverted state represents a NOT function, thereby realizing logical functions of the digital circuit.

FIG. 5 is a schematic diagram showing conversion of a circuit into an AIG format. Each node in the AIG performs a AND function, and each edge represents a connection relationship. Solid lines are direct connections, while dashed lines denote connections with logical inversion.

In this embodiment, an open-source tool abc is used to convert the Verilog files describing the digital logic circuits into aiger text format. A Python package pyaig and networks are used to generate a corresponding AIG based on the node connection relationship and edge information described in the aiger text file.

In S102, a circuit critical path is marked.

The circuit critical path is marked on the digital logic circuit conversion graph obtained in the step S101. The circuit critical path is a path with longest delay in the digital logic circuit, that is, a path with most levels in the digital logic circuit conversion graph.

The marking the circuit critical path includes: performing a depth-first search on all POs (Primary Outputs) in the digital logic circuit, traversing a child node of each node in all paths from the POs; for each child node, determining that the child node belongs to the circuit critical path if it is not a PI (Primary Input) and its level number is one less than that of its parent node; otherwise, determining that the child node does not belong to the circuit critical path; and repeating the traversing and determining steps until all nodes belonging to the circuit critical path are identified.

Corresponding nodes and edges between the nodes are found out on the digital logic circuit conversion graph obtained in the step S101 for all critical path nodes, and are marked as the critical path. A to-be-partitioned circuit representation graph with critical path information is obtained.

In S103, the partitioning model is trained.

Partitioning operations are performed on the to-be-partitioned circuit representation graph with critical path information by using a reinforcement learning A2C model, and a single-step partitioning reward function rₜ is calculated to update model parameters.

Introducing critical path factors into a reward function trained by the model enables the partitioning model to consider circuit critical paths during partitioning operation, so that the partitioning operations cut the critical paths as little as possible.

The partitioning operation is that all nodes in the graph obtained in the step S101 are in the same partition, such as a No. 0 partition, a strategy is calculated by the reinforcement learning partitioning model, sampling is performed based on the strategy to redetermine partitions for each node, i.e., new partition numbers are assigned. After obtaining the node partition data, a reinforcement learning partitioning loss function is calculated to update the model parameters.

The single-step loss function during the training the reinforcement learning A2C model is:

$$L ( θ ) = - {\sum }_{t = 0}^{T - 1} log {π}_{θ} ( {a}_{t} \vert {s}_{t} ) ( {R}_{t} - {v}_{θ} ( {s}_{t} ) ) + α {\sum }_{t = 0}^{T - 1} {( {R}_{t} - {v}_{θ} ( {s}_{t} ) )}^{2}$$

where θ represents a model parameter, sₜ represents a graph state at time t, aₜ represents an action selected at time t, π_{θ}(aₜ|sₜ) represents probability distribution of aₜ at sₜ, v_{θ}(sₜ) represents an estimated value of sₜ, α represents a loss coefficient, 0<α≤1 is used for stabilizing the training process, in this embodiment, α is set as 0.1.

Rₜ represents a cumulative reward function, which is:

$${R}_{t} = {\sum }_{k = 0}^{T - t - 1} {γ}^{k} {r}_{t + 1 + k}$$

where γ represents a discount factor, if it is close to 0, our perspective on the training process is short-sighted, whereas if it is close to 1, actions occurring further in time are also relevant to the calculation of rewards, in this embodiment, γ is set as 1, which indicates that the reward for a singe step is independent of time, and rₜ₊₁₊ₖ represents a single-step reward function at time t+1+k.

The single-step reward function rₜ at time t after introducing the circuit critical path is:

$${r}_{t} = [ n c ( {s}_{t} ) - n c ( {s}_{t + 1} ) ] {δ}^{m}$$

$$nc ( G ) = c u t ( G ) ( \frac{1}{vol ( {V}_{1} )} + \frac{1}{vol ( {V}_{2} )} + … + \frac{1}{vol ( {V}_{n} )} )$$

$$vol ( {V}_{Q} ) = {\sum }_{v ∈ {V}_{Q}} deg ( v )$$

where sₜ₊₁ is a graph state after performing a single-step partitioning operation; δ is a critical path factor; 1<δ≤1; m is a number of times the critical path is cut for current partitioning; i.e., whether nodes and edges involved in the partitioning belong to the nodes and edges on the critical path; nc is a partitioning normalization function, which is used to define the quality of the partition; G is a graph state after partitioning; V₁-Vₙ represent partitions 1-n; vol is a partitioning volume function; cut function counts a number of edges cut by partitioning; Q∈[1, n], v is a node belonging to partition V_{Q}, and deg(v) is a node degree function, which counts the number of all edges connected to that node.

In S104, the steps S101 to S103 are repeated on all the digital logic circuits in the dataset, until the reinforcement learning partitioning model converges, and a partitioning agent model for the circuit critical path is obtained.

In S2, the digital logic circuit is partitioned by using the reinforcement learning partitioning agent model for the critical path of the digital logic circuit.

The step 2 includes S201-S202, the flow chart of which is shown in FIG. 3.

In S201, graph partitioning is performed on the digital logic circuit.

The digital logic circuit to be partitioned is converted into an AIG format, which is input into a trained reinforcement learning graph partitioning model for partitioning, so as to obtain graph partitioning information about the critical path.

In S202, circuit partitioning is performed on the digital logic circuit.

The graph partitioning information is converted into node partitioning information, circuit partitioning is performed on the original digital logic circuit based on the node partitioning information.

The partitioning information of nodes in the graph partition is stored in a text format. The storing method is as follows: the partitioning information is stored according to the node order. For example, if node 1 belongs to partition 2, then the first line of the text is 2; if node 8 belongs to partition 0, then the eighth line of the text is 0. The above operation is performed for all nodes in the AIG converted from the logic circuit to obtain the partitioning text.

The partition text is read, and each node of the original digital logic circuit is traversed for each partition. The partitioned circuits are constructed based on the partitioning information of each node in the circuit, which is specifically as follows. If the node itself is a PI or PO of the original circuit, it is added as a PI or PO in the partitioned circuit. If the node is not a PI or PO and a fan-in node of the node belongs to the same partition as the node, then the node is added to the partitioned circuit. If the node is not a PI or PO and the fan-in node of the node does not belong to the same partition as the node, then the fan-in node is added as a PI in the partitioned circuit. If the node is not a PI or PO and a fan-out node of the node does not belong to the same partition as the node, then the fan-out node is added as a PO in the new partitioned circuit. If the node is not a PI or PO and the fan-out node of the node belongs to the same partition as the node, then the node is added to the partitioned circuit.

In S3, the partitioned circuits are automatically explored for optimization space by using a reinforcement learning exploration model.

In the step S3, traditional optimization solution is usually optimized by a single structure, and only optimization space of the single structure is explored, which prevents comprehensive optimization of the circuit. After single-step optimization, the circuit structure changes, and current optimization operators and structures are no longer suitable for the optimized circuit structure. Therefore, a larger optimization space is introduced. The optimization space includes four circuit representation forms, namely: AIG (And Inverter Graphs), MIG (Majority Inverter Graphs), XAG (Xor-And Graphs), and XMG (Xor-Majority Graphs). Various optimization operators under these four representation forms are: rewrite, rewrite −z (zero-gain rewrite permitted), refactor, refactor −z (zero-gain refactor permitted), resub, and balance.

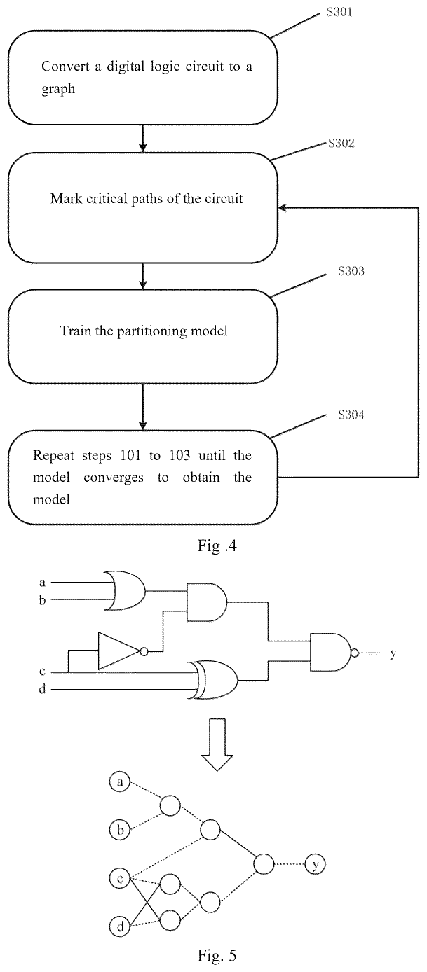

The step 3 includes substeps S301-S304, the flowchart of which is shown in FIG. 4.
S301: initializing:

Each partitioned circuit is initialized, the optimization environment is determined, which includes the technology library and timing constraints, and the exploration iteration length is set.
s302: selecting an optimization operator

The features of the partitioned circuit are extracted. The standardized results of these features of the partitioned circuit, and history data of various optimization operators are fed into the reinforcement learning A2C model. The most suitable optimization operator for the current partitioned circuit is obtained.

The features of the partitioned circuit include: a number of nodes and edges after the circuit is converted into a graph, a number of levels in the circuit corresponding AIG, a number of latches in the circuit, a proportion of “AND” gates and “NOT” gates in the circuit, a maximum number of fan-ins and fan-outs of the digital logic circuit after process mapping, and an average number of fan-ins and fan-outs of logic nodes.

The extraction of partitioning features is performed using a stat command from the open-source tool yosys and a print_stats command from the open-source tool abc. The process mapping is carried out using the map command from the open-source tool abc.
s303: optimizing the partitioned circuit:

The partitioned circuit is optimizing based on the selected optimizing operator, and the single-step optimization reward function is calculated to update the reinforcement learning optimizing model.

If the optimization operators belong to different structures, structural transformation of the circuit is required. This transformation is performed using the open-source tool mockturtle developed by EPFL.

The single-step optimized reward function during the exploring process is:

$$r ( k ) = v ( {s}_{k} ) - v ( {s}_{k + 1} )$$

$$v ( {s}_{k} ) = c * {V}_{delay} + ( 1 - c ) * {V}_{area}$$

where V_{delay} and Vₐᵣₑₐ are delay and area of the partitioned circuit after the process mapping using a specified technology library, respectively, c is a weight coefficient used to adjust pertinence of the model to an optimization target, sₖ represents a state of the circuit at time k, k represents an iteration count. The process mapping step is implemented using the map command from the open-source tool abc.

In S304, steps S302 and S303 are repeated until a maximum iteration count is reached, and a plurality of optimized partitioned circuits are obtained.

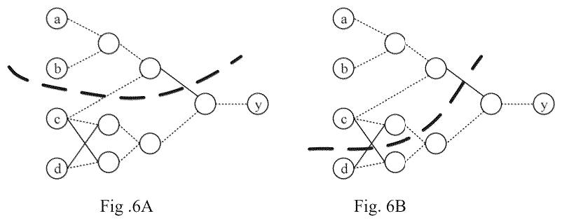

FIG. 6 shows a schematic diagram of two different partitions of the same digital circuit. In partitioning of FIG. 6A, the critical path is not cut, whereas in partitioning of FIG. 6B, the critical path is cut three times. The cut count δ^{m} of the critical path in the reward function is equal to δ³.

In Step S4, based on partitioning information of the original node, POs of each optimized partitioned circuit are traversed. It is determined whether a PO belongs to the original digital logic circuit. If so, it is added as a PO in the merged circuit; if not, it is identified as an internal node from the original circuit and added as an internal node to the merged circuit.

Internal nodes of each optimized partitioned circuit are traversed, and the corresponding internal nodes are added accordingly to the merged circuit.

PIs of each optimized partitioned circuit are traversed. It is determined whether a PI belongs to the original digital logic circuit. If so, it is added as a PI in the merged circuit; if not, it is identified as an internal node from the original circuit and added as an internal node to the merged circuit.

Based on the original partitioning information, POs of each optimized partitioned circuit are traversed. It is determined whether a PO belongs to the original digital logic circuit. If so, it is added as a PO in the merged circuit; if not, it is identified as an internal node from the original circuit and added as an internal node to the merged circuit.

The internal nodes of each optimized partitioned circuit are traversed, and the corresponding internal nodes are added accordingly to the merged circuit.

The PIs of each optimized partitioned circuit are traversed. It is determined whether a PI belongs to the original digital logic circuit. If so, it is added as a PI in the merged circuit; if not, it is identified as an internal node from the original circuit and added as an internal node to the merged circuit.

After the partitioned circuits are merged, the optimized circuit is obtained. Based on the layout of this optimized circuit, the circuit hardware is fabricated.

In this embodiment, in the open-source technology library ASAP7 and EPFL combinational logic circuit benchmark, improvements of 5.8% in area, 16.9% in delay, and 20.2% in area-delay product are achieved respectively. The area-delay product refers to a product of the area and delay of the digital logic circuit after process mapping, and the overall quality of the circuit is reflected.

TABLE 1

| | Original Circuit | | | Embodiment | | |
|---|---|---|---|---|---|---|
| | | | Area-Delay | | | Area-Delay |
| | Area | Delay | Product | Area | Delay | Product |
| | (μm²) | (ns) | (μm²*ns) | (μm²) | (ns) | (μm²*ns) |
| adder | 867.34 | 2.03 | 1760.70 | 946.42 | 1.48 | 1405.02 |
| bar | 2499.13 | 1.04 | 2599.10 | 1241.05 | 0.93 | 1148.77 |
| max | 1427.67 | 4.48 | 6395.96 | 1924.79 | 4.10 | 7887.90 |
| multiplier | 19617.21 | 3.83 | 75133.91 | 19070.64 | 3.23 | 61612.85 |
| sin | 3844.22 | 3.65 | 14211.06 | 3467.71 | 3.52 | 12211.61 |
| sqrt | 11719.99 | 329.46 | 3861267.91 | 6740.16 | 170.21 | 1147269.39 |
| square | 19633.78 | 7.63 | 149805.74 | 20083.08 | 6.55 | 131568.47 |
| div | 11552.73 | 84.32 | 974126.19 | 13130.87 | 78.17 | 1026422.78 |

| | |
|---|---|
| Average Area Improvement | 5.8% |
| Average Delay Improvement | 16.9% |
| Average Area-Delay Product Improvement | 20.2% |

In summary, with the above logic optimization method, in the present application, the digital logic circuit may be partitioned based on to heterogeneous features and the critical path information of the original circuit, so as to obtain the circuit partitioning results with the least influence on the critical path. Furthermore, the optimal optimization structures and operators for the next state are automatically explored within the optimization space of each partition, rather than optimizing solely on a single-structure complete circuit. Compared to traditional optimization methods, the method enables a deeper exploration of the optimization space, achieving optimized structures and processes for area and delay of a given digital logic circuit. In addition, the automated exploring process requires no manual intervention, reducing the labor costs associated with chip design optimization.

Additionally, in this embodiment, the execution entity of the method for generative heterogeneous logic optimization based on critical path partitioning is a dedicated computer device system, which includes a memory and a processor interconnected via a physical bus architecture.

The memory stores executable codes. When the processor executes the executable codes, it implements the method described in the embodiments. Specifically, the processor in the computer device executes the AIG conversion process, the AIG partitioning process, the circuit partitioning process based on graph partitioning, the optimizing process of the partitioned circuit, and the merging process of the optimized partitioned circuits.

The memory may include high-speed random access memory (RAM) and may also include non-volatile memory, such as at least one disk storage unit. Communication between the system element and at least one other system element is achieved by at least one communication interface (which may be wired or wireless) over networks such as Internet, wide area networks, local area networks, or metropolitan area networks. The bus may be an ISA bus, PCI bus, EISA bus, etc. The bus may include an address bus, data bus, control bus, etc. The memory is used to store programs. When the processor receives an execution instruction, it executes the program. The method implemented by the apparatus defined by the processes disclosed in any embodiment of the present application may be applied to or implemented by the processor.

The processor may be an integrated circuit chip with signal processing. In the implementation, the steps of the above method may be implemented by integrated logic circuits in the hardware of the processor or by instructions in the form of software. The processor may be a general-purpose processor, including a central processing unit (CPU), network processor (NP), etc., or may be a digital signal processor (DSP), application-specific integrated circuit (ASIC), field-programmable gate array (FPGA), or other programmable logic devices, discrete gate or transistor logic devices, or discrete hardware components. The method, steps, and logic block diagrams disclosed in the embodiments of the present application may be implemented or performed. The general-purpose processor may be a microprocessor, or may be any conventional processor, etc. The steps of the methods disclosed in combination with the embodiments of the present application may be directly implemented by a hardware decoding processor, or by a combination of hardware and software modules in the decoding processor. Software modules may reside in mature storage media in the field, such as random access memory, flash memory, read-only memory, programmable read-only memory, electrically erasable programmable memory, or registers. The storage medium is located in the memory, and the processor reads information from the memory and completes the steps of the above method in combination with its hardware.

In some other embodiments, the AIG graph conversion process may be implemented by using an AIG graph parser realized on an FPGA. Specifically, the FPGA may be configured to process the logical function descriptions in Verilog files in parallel and quickly convert them into the AIG graph format. It includes efficient syntax and semantic parsers configured to interpret “AND” and “NOT” operations and construct the corresponding AIG graph nodes and edge representations in real time. The high parallelism and reconfigurability of the FPGA enable rapid AIG graph generation for digital logic circuits with varying scales and complexities. The generated AIG graph data may be transmitted to the processor and memory of the above dedicated computer device system via high-speed data interfaces (e.g., PCIe bus or custom inter-chip connections) for subsequent partitioning and optimization.

The AIG graph partitioning process may be implemented using a graphics processing unit (GPU). With massive parallel computing capabilities, the GPU is particularly suitable for performing complex calculations in graph partitioning algorithms, such as partitioning operations on the circuit representation graph with critical path information based on the reinforcement learning A2C model (e.g., the A2C model consists of a critic network and an actor network, and updates the policy gradient via the advantage function). The numerous processing cores of the GPU may execute neural network inference and training processes in parallel, accelerate policy computation and action sampling, and efficiently calculate the single-step partitioning reward function and update model parameters. The parallel processing capability significantly reduces the time required for model training and partition generation.

The optimized partitioned circuit process may be implemented by using parallel optimization processing units realized on DSPs or FPGAs. These units may optimize multiple partitioned circuits in parallel. DSPs may efficiently perform complex mathematical operations, which are suitable for feature extraction in the reinforcement learning optimization model (such as the number of nodes, number of edges, number of levels, etc.), optimization operator selection, and reward function calculation. FPGAs may be customized to implement hardware accelerators for various optimization operators, for example, specialized for performing operations like rewriting or balancing under different circuit representations such as AIG, MIG, XAG, and XMG. Through parallel computing, these units may accelerate the calculation of the single-step optimization reward function and the update of the reinforcement learning optimization model, thereby efficiently exploring the optimization space before reaching the maximum iteration count.

The merging process of optimized partitioned circuits may be implemented using a CPU. The CPU may be designed to efficiently traverse and merge various optimized partitioned circuits based on partitioning information of the original nodes. This includes correctly identifying and processing POs, internal nodes, and PIs of the original digital logic circuit and appropriately adding them to the merged circuit. The CPU may execute multi-threaded or parallel algorithms to process node and edge information from different partitioned circuits and quickly construct the final optimized complete digital logic circuit, thereby supporting subsequent circuit layout and hardware fabrication.

What is claimed is:

1. A method for generative heterogeneous logic optimization based on critical path partitioning, comprising:
step S1: constructing a reinforcement learning partitioning agent model for a critical path of a digital logic circuit;
step S2: partitioning the digital logic circuit using the reinforcement learning partitioning agent model for the critical path of the digital logic circuit to obtain a plurality of partitioned circuits;
step S3: automatically exploring optimization space on the plurality of partitioned circuits by a reinforcement learning optimization model to obtain a plurality of optimized partitioned circuits;
step S4: merging the optimized partitioned circuits to obtain a final optimization result;
wherein the step S1 comprises:
S101: constructing a digital logic circuit conversion graph:
acquiring different digital logic circuits to construct a dataset;
converting the digital logic circuits in the dataset into an AIG (And-Inverter Graph) format, to obtain the digital logic circuit conversion graph;
simplifying logic functions into AND and NOT operations based on logic function description in an original digital logic circuit, wherein in the digital logic circuit conversion graph, each node represents an AND function, each edge represents a connection relationship between nodes, and each edge in an inverted state represents a NOT function;
S102: marking a circuit critical path:
marking the circuit critical path on the digital logic circuit conversion graph obtained in the step S101, wherein the circuit critical path is a path with longest delay in the digital logic circuit, that is, a path with most levels in the digital logic circuit conversion graph;
finding out corresponding nodes and edges between nodes on the digital logic circuit conversion graph obtained in the step S101 for all critical path nodes, marking them as the critical path, and obtaining a to-be-partitioned circuit representation graph with critical path information;
S103: performing partitioning operations on the to-be-partitioned circuit representation graph with critical path information using a reinforcement learning A2C model, and calculating a single-step partitioning reward function rₜ to update model parameters;
S104: repeating steps S101 to S103 for all digital logic circuits in the dataset until the reinforcement learning A2C model converges, thereby obtaining the reinforcement learning partitioning agent model for the critical path of the digital logic circuit.

2. The method of claim 1, wherein in step S102, the marking the circuit critical path comprises: performing a depth-first search on all POs (Primary Outputs) in the digital logic circuit; traversing a child node of each node in all paths from the POs; for each child node, determining that the child node belongs to the circuit critical path if it is not a PI (Primary Input) and its level number is one less than that of its parent node; otherwise, determining that the child node does not belong to the circuit critical path; and repeating traversing and determining steps until all nodes belonging to the circuit critical path are identified.

3. The method of claim 1, wherein in step S103, the single-step loss function during the training the reinforcement learning A2C model is:
$$L ( θ ) = - {\sum }_{t = 0}^{T - 1} log {π}_{θ} ( {a}_{t} \vert {s}_{t} ) ( {R}_{t} - {v}_{θ} ( {s}_{t} ) ) + α {\sum }_{t = 0}^{T - 1} {( {R}_{t} - {v}_{θ} ( {s}_{t} ) )}^{2} \qquad ( 1 )$$
$${R}_{t} = {\sum }_{k = 0}^{T - t - 1} {γ}^{k} {r}_{t + 1 + k} \qquad ( 2 )$$
where θ represents a model parameter, sₜ represents a graph state at time t, aₜ represents an action selected at time t, π_{θ}(aₜ|sₜ) represents probability distribution of aₜ at sₜ, v_{θ}(sₜ) represents an estimated value of sₜ, α represents a loss coefficient, Rₜ represents a cumulative reward function, γ represents a discount factor, rₜ₊₁₊ₖ represents a single-step reward function at time t+1+k;
the single-step reward function rₜ at time t after introducing the circuit critical path, is:
$${r}_{t} = [ n c ( {s}_{t} ) - n c ( {s}_{t + 1} ) ] {δ}^{m} \qquad ( 3 )$$
$$nc ( G ) = c u t ( G ) ( \frac{1}{vol ( {V}_{1} )} + \frac{1}{vol ( {V}_{2} )} + … + \frac{1}{vol ( {V}_{n} )} ) \qquad ( 4 )$$
$$vol ( {V}_{Q} ) = {\sum }_{v ∈ {V}_{Q}} deg ( v ) \qquad ( 5 )$$
where sₜ₊₁ is a graph state after a single-step partitioning operation; δ is a critical path factor; m is a number of times the critical path is cut for current partitioning; nc is a partitioning normalization function; G is a graph state after partitioning; Vn represents partition n; vol is a partitioning volume function; cut function counts a number of edges cut by partitioning; Q is a partition index; Q∈[1, n], deg(v) is a degree function of nodes.

4. The method according to claim 1, wherein the step S2 comprises:
S201: performing graph partitioning on the digital logic circuit:
converting the digital logic circuit to be partitioned into an AIG format, and inputting it into a trained reinforcement learning graph partitioning agent model for partitioning, to obtain graph partitioning information with the critical path;
S202: performing circuit partitioning on the digital logic circuit:
converting the graph partitioning information into node partitioning information; performing circuit partitioning on the original digital logic circuit based on the node partitioning information; and traversing each node of the original digital logic circuit for each circuit partition, and constructing a partitioned circuit based on partitioning information of each node.

5. The method of claim 4, wherein in the step S202, the constructing the partitioned circuit based on the partitioning information of each node comprises:
traversing each node in each circuit partition, if the current node is a PI or PO of the original digital logic circuit, adding it as a PI or PO in the partitioned circuit; if the current node is neither a PI nor a PO, and a fan-in node of the current node belongs to a same partition as the current node, adding the current node to the partitioned circuit; if the current node is neither a PI nor a PO, and a fan-in node of the current node does not belong to the same partition as the current node, adding the fan-in node as a PI in the partitioned circuit; if the current node is neither a PI nor a PO, and a fan-out node of the current node does not belong to the same partition as the current node, adding a fan-out node of the current node as a PO in the partitioned circuit; if the current node is neither a PI nor a PO, and a fan-out node of the current node belongs to the same partition as the current node, adding the current node to the partitioned circuit.

6. The method of claim 1, wherein the step S3 comprises:
S301: initializing:
initializing each partitioned circuit to determine an optimization environment and set an exploration iteration length;
S302: selecting an optimization operator:
extracting features of the partitioned circuit, and feeding a result obtained after standardizing the features of the partitioned circuit and history data of a plurality of optimization operators into the reinforcement learning optimization model, to select a most suitable optimization operator for the current partitioned circuit;
S303: optimizing the partitioned circuit:
optimizing the partitioned circuit based on the selected optimizing operator, and calculating a single-step optimization reward function to update the reinforcement learning optimizing model;
S304: repeating steps S302 and S303 until a maximum iteration count is reached, and obtaining a plurality of optimized partitioned circuits.

7. The method of claim 1, wherein in the step S302, the features of the partitioned circuit comprise a number of nodes in the digital logic circuit conversion graph, a number of edges, a number of levels of the circuit corresponding to the AIG, a number of latches, a proportion of AND gates and NOT gates; a maximum number of fan-ins and a maximum number of fan-outs of the digital logic circuit after process mapping, and an average number of fan-ins and an average number of fan-outs of logic nodes.

8. The method of claim 6, wherein in the step S303, the single-step optimized reward function is:
$$r ( k ) = v ( {s}_{k} ) - v ( {s}_{k + 1} ) \qquad ( 6 )$$
$$v ( {s}_{k} ) = c * {V}_{delay} + ( 1 - c ) * {V}_{area} \qquad ( 7 )$$
where V_{delay} and Vₐᵣₑₐ are a delay and an area, respectively, of the partitioned circuit after the process mapping, c is a weight coefficient, sₖ represents a state of the circuit at time k, k represents an iteration count.

9. The method according to claim 1, wherein the step S4 is as follows:
based on partitioning information of each original node, traversing a PO of each optimized partitioned circuit, determining whether the PO is a PO of the original digital logic circuit, if so, adding the PO as a PO in the merged circuit, and if not, indicating that the PO is an internal node in the original digital logic circuit, and adding the internal node to the merged circuit;
traversing internal nodes of each optimized partitioned circuit, and adding corresponding internal nodes in the merged circuit correspondingly;
traversing a PI of each optimized partitioned circuit, determining whether the PI is a PI of the original digital logic circuit, if so, adding the PI as a PI in the merged circuit, and if not, indicating that the PI is an internal node in the original digital logic circuit, and adding the internal node to the merged circuit.
